(19) United States
(12) Patent Application Publication
(10) Pub. No.: US 2009/0283144 A1
(43) Pub. Date: Nov. 19, 2009

(54) SOLAR CONCENTRATING MIRROR

(75) Inventors: TIMOTHY J. HEBRINK, Scandia, MN (US); Tracy L. Anderson, Hudson, WI (US); Susannah C. Clear, Hastings, MN (US); Andrew K. Hartzell, Hudson, WI (US); Edward J. Kivei, Stillwater, MN (US)

Correspondence Address: 3M INNOVATIVE PROPERTIES COMPANY, PO BOX 33427, ST. PAUL, MN, 55133-3427, US

(73) Assignee: 3M Innovative Properties company

(21) Appl. No.: 12/466,034

(22) Filed: May 14, 2009

Related U.S. Application Data
(63) Continuation-in-part of application No. 12/120,258, filed on May 14, 2008.

(51) Int. Cl. H01L 31/00

(52) U.S. Cl. 136/259

(57) ABSTRACT

An article that is suitable for use as a solar concentrating mirror for enhancing the use of solar collection devices, such as solar cells. The article includes a multilayer optical film and a compliant UV protective layer. The article addresses degradation issues in solar concentration devices, provides specific bandwidths of electromagnetic energy to the solar cell while eliminating or reducing undesirable bandwidths of electromagnetic energy that may degrade or adversely affect the solar cell, and renders a compliant sheet of material that may be readily formed into a multitude of shapes or constructions for end use applications. A solar collection device comprising the article and optionally comprising a celestial tracking mechanism is also disclosed.

### CROSS-REFERENCE TO RELATED APPLICATIONS

This application is a continuation-in-part of U.S. application Ser. No. 12/120258, filed on May 14, 2008, the disclosure of which is incorporated herein by reference in its entirety.

### TECHNICAL FIELD

This invention relates to wavelength selective mirrors suitable for application as solar concentrators for improving the efficiency and operation of solar cells.

### BACKGROUND

Conventional solar concentrating mirrors are typically used to direct broad bandwidths of solar energy onto a solar cell or solar heat transfer element. However, electromagnetic radiation of certain wavelengths reflected from the solar concentrating mirror onto the solar element may adversely affect the solar element. For example, wavelengths in the infrared spectrum can cause certain solar cells to undesirably increase in temperature. As a result, the solar cells may lose efficiency, and degrade over time due the excessive thermal exposure. Long term exposure to ultraviolet (UV) light also typically leads to premature degradation of components of the solar cell.

The materials employed in the construction of solar concentrating mirrors may comprise compositions that are adversely affected by specific bandwidths of electromagnetic radiation. Degradation of those materials will cause a drop in concentrating efficiency and potentially the complete failure of the solar concentrating mirror. Long term exposure to UV light is one exemplary condition that often leads to premature degradation of materials exposed to sunlight.

### SUMMARY

The present invention is directed to an article that is suitable for use as a solar concentrating mirror for enhancing the use of solar collection devices, such as solar cells. The article is a unique combination of layered compositions that: (i) address degradation issues in solar concentration devices, (ii) provide specific bandwidths of electromagnetic energy to the solar cell while eliminating or reducing undesirable bandwidths of electromagnetic energy that may degrade or adversely affect the efficacy of the solar cell, and (iii) render a compliant sheet of material that may be readily formed into a multitude of shapes or constructions for end use applications.

The article comprises a multilayer optical film and a compliant UV protective layer. The multilayer optical film has an optical stack that includes a plurality of alternating layers, the alternating layers having at least one birefringent polymer layer and at least one second polymer layer.

The compliant UV protective layer is applied onto a surface of the multilayer optical film to create an article that may be used as a solar concentrating mirror for concentrating a specific bandwidth of light onto a solar cell. For purposes of the invention, light is intended to mean solar irradiance. The resulting article reflects at least a major portion of the average light across the range of wavelengths that corresponds with the absorption bandwidth of a selected solar cell and either transmits or absorbs a major portion of light outside the absorption bandwidth of the selected solar cell.

The article is a compliant sheet of material that may be readily formed into various shapes or constructions. For example, the article may be thermoformed into troughs, parabolic shapes, etc. In one embodiment, the article may be formed around the solar cell in order to focus electromagnetic energy onto more than one surface of the solar cell.

The present invention also provides a solar collection device comprising:
(a) one or more solar cells having an absorption bandwidth; and
(b) at least one solar concentrating mirror positioned in proximity to the one or more solar cells, wherein the at least one solar concentrating mirror comprises (i) a multilayer optical film having an optical stack having a plurality of alternating layers, the alternating layers having at least one birefringent polymer and at least one second polymer; and (ii) a UV protective layer applied onto a surface of the multilayer optical film, wherein the solar concentrating mirror reflects at least a major portion of the average light across the range of wavelengths that corresponds with the absorption bandwidth of the solar cell onto the solar cell and does not reflect onto the solar cell a major portion of light outside the absorption bandwidth of the solar cell.

The solar cells suitable for use with the novel solar concentrating mirror and/or in the solar collection device disclosed herein include both silicon based and non-silicon based materials. The constructions may include single junction cells and multi-junction cells. In application and use, the article and solar cell combinations may be placed into arrays and further incorporated into celestial tracking mechanisms.

### BRIEF DESCRIPTION OF DRAWINGS

FIG. 1 is a schematic cross sectional view of the article of the present invention with an optional durable top coat layer depicted in phantom;

FIG. 2 is a schematic view of a solar cell and one embodiment of an article of the present invention;

FIG. 3 is a schematic view of another embodiment of the present invention in combination with a solar cell;

FIGS. 4a, 4b, and 4c are graphical representations of the solar irradiation and absorption spectrum of various solar cells and the operating window created by the concentrating mirror of the present invention;

FIG. 5a is a schematic overhead view of an array of solar cells with multiple articles of the present invention;

FIG. 5b is a schematic cross sectional view of the embodiment of FIG. 5a with optional protective layers in phantom;

FIG. 5c is schematic cross sectional view of FIG. 5a depicting an alternative embodiment of a thermoformed article around multiple solar cells;

FIG. 6 is a schematic cross sectional view depicting a thermoformed article of an array of multiple solar concentrating mirrors;

FIG. 7 is a schematic diagram of an embodiment of a tracker for moving linear compound parabolic concentrator assemblies mounted in a frame;

FIG. 8a is a diagram showing an embodiment of an array of solar cells with louvers comprising the solar concentrating mirrors disclosed herein, wherein the louvers are oriented to enhance capture of rays from the morning sun;

FIG. 8b is a diagram showing an embodiment of an array of solar cells with louvers comprising the solar concentrating mirrors disclosed herein, wherein the louvers are oriented to enhance capture of rays from the mid-day sun; and

FIG. 8c is a diagram showing an embodiment of an array of solar cells with louvers comprising the solar concentrating mirrors disclosed herein, wherein the louvers are oriented to enhance capture of rays from the evening sun.

### DETAILED DESCRIPTION

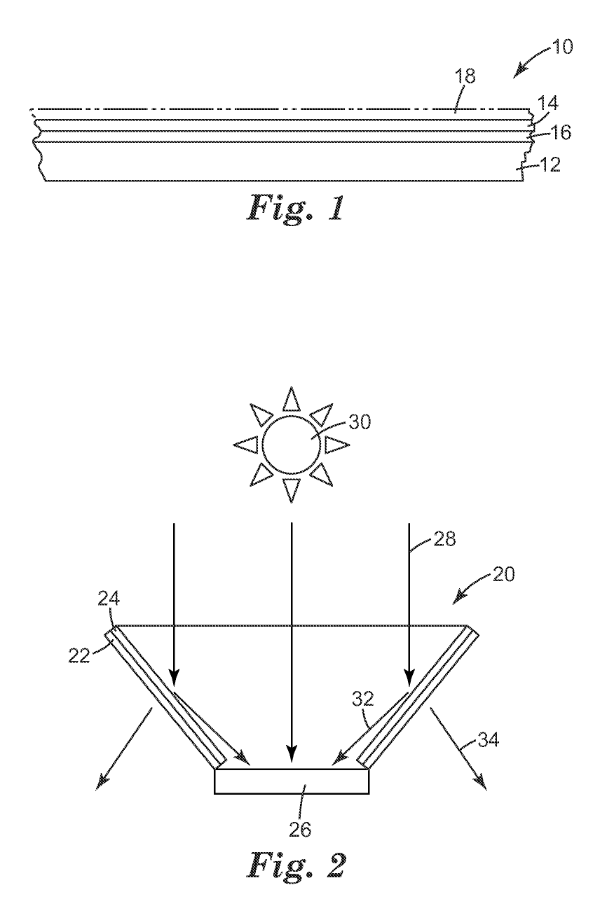

FIG. 1 depicts the article 10 of the present invention. The article 10 comprises a multilayer optical film 12 and a compliant UV protective layer 14 that in application serves as a solar concentrating mirror. The multilayer optical film has an optical stack that includes a plurality of alternating layers (not shown). The alternating layers of the multilayer optical film 12 include at least one birefringent polymer layer and at least one second polymer layer.

The compliant UV protective layer 14 is applied onto a surface of the multilayer optical film 12 to create the article 10 that may be used as a solar concentrating mirror for concentrating light onto a solar cell (not shown). The resulting article 10 reflects at least a major portion of the average light across the range of wavelengths that corresponds with the absorption bandwidth of a selected solar cell and either transmits or absorbs a major portion of light outside the absorption bandwidth of the selected solar cell. Optional tie layer 16 and durable top coat 18 may also be employed in an alternative embodiment of article 10.

The UV protective layer 14, and therefore article 10, is generally a compliant sheet of material. For purposes of the present invention, the term compliant is an indication that article 10 is dimensionally stable yet possesses a pliable characteristic that enables subsequent molding or shaping into various forms. Preferably, the compliant film has less than 10% film formers in the UV protective layer 14. According to the present description, film formers may be crosslinking agents or other multifunctional monomers. In a most preferred embodiment, article 10 may be thermoformed into various shapes or structures for specific end use applications.

FIG. 2 illustrates a general application of the article 20 as a solar concentrating mirror. Article 20 comprises a multilayer optical film 22 and a UV protective layer 24 positioned in close proximity to a solar cell 26. The article 20 receives electromagnetic radiation 28 from the sun 30. A select bandwidth 32 of the electromagnetic radiation 28 is reflected onto solar cell 26. An undesirable bandwidth 34 of electromagnetic radiation passes through article 20 and is not reflected onto solar cell 26.

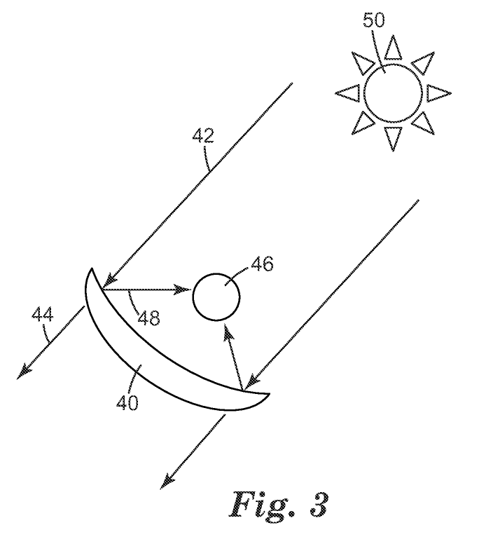

FIG. 3 is another general embodiment depicting the inventive article in the form of a parabolic solar concentrating mirror 40. Electromagnetic radiation 42 from the sun 50 is received by the parabolic solar concentrating mirror 40. A preferred bandwidth 48 is reflected onto a solar cell 46 while an undesirable bandwidth 44 of electromagnetic radiation passes through the parabolic solar concentrating mirror 40 and is not reflected onto the solar cell 46 where it could potentially alter the operational efficiency of the solar cell. The shape of the article may include parabolic or other curved shapes, such as for example sinusoidal.

### Multilayer Optical Films

Conventional multilayer optical films with alternating layers of at least one birefringent polymer and one second polymer may be employed in creating the article of the present invention. The multilayer optical films are generally a plurality of alternating polymeric layers selected to achieve the reflection of a specific bandwidth of electromagnetic radiation.

Materials suitable for making the at least one birefringent layer of the multilayer optical film of the present disclosure include polymers (e.g., polyesters, copolyesters, and modified copolyesters). In this context, the term “polymer” will be understood to include homopolymers and copolymers, as well as polymers or copolymers that may be formed in a miscible blend, for example, by co-extrusion or by reaction, including transesterification. The terms “polymer” and “copolymer” include both random and block copolymers. Polyesters suitable for use in some exemplary multilayer optical films constructed according to the present disclosure generally include carboxylate and glycol subunits and can be generated by reactions of carboxylate monomer molecules with glycol monomer molecules. Each carboxylate monomer molecule has two or more carboxylic acid or ester functional groups and each glycol monomer molecule has two or more hydroxy functional groups. The carboxylate monomer molecules may all be the same or there may be two or more different types of molecules. The same applies to the glycol monomer molecules. Also included within the term “polyester” are polycarbonates derived from the reaction of glycol monomer molecules with esters of carbonic acid.

Suitable carboxylate monomer molecules for use in forming the carboxylate subunits of the polyester layers include, for example, 2,6-naphthalene dicarboxylic acid and isomers thereof, terephthalic acid; isophthalic acid; phthalic acid; azelaic acid; adipic acid; sebacic acid; norbornene dicarboxylic acid; bi-cyclo-octane dicarboxylic acid; 1,4-cyclohexane dicarboxylic acid and isomers thereof, t-butyl isophthalic acid, trimellitic acid, sodium sulfonated isophthalic acid; 4,4′-biphenyl dicarboxylic acid and isomers thereof, and lower alkyl esters of these acids, such as methyl or ethyl esters. The term “lower alkyl” refers, in this context, to C1-C10 straight-chained or branched alkyl groups.

Suitable glycol monomer molecules for use in forming glycol subunits of the polyester layers include ethylene glycol; propylene glycol; 1,4-butanediol and isomers thereof, 1,6-hexanediol; neopentyl glycol; polyethylene glycol; diethylene glycol; tricyclodecanediol; 1,4-cyclohexanedimethanol and isomers thereof; norbornanediol; bicyclo-octanediol; trimethylol propane; pentaerythritol; 1,4-benzenedimethanol and isomers thereof, bisphenol A; 1,8-dihydroxy biphenyl and isomers thereof, and 1,3-bis (2-hydroxyethoxy)benzene.

An exemplary polymer useful as the birefringent layer in the multilayer optical films of the present invention is polyethylene naphthalate (PEN), which can be made, for example, by reaction of naphthalene dicarboxylic acid with ethylene glycol. Polyethylene 2,6-naphthalate (PEN) is frequently chosen as a birefringent polymer. PEN has a large positive stress optical coefficient, retains birefringence effectively after stretching, and has little or no absorbance within the visible range. PEN also has a large index of refraction in the isotropic state. Its refractive index for polarized incident light of 550 nm wavelength increases when the plane of polarization is parallel to the stretch direction from about 1.64 to as high as about 1.9. Increasing molecular orientation increases the birefringence of PEN. The molecular orientation may be increased by stretching the material to greater stretch ratios and holding other stretching conditions fixed. Copolymers of PEN (CoPEN), such as those described in U.S. Pat. No. 6,352,761 and U.S. Pat. No. 6,449,093 are particularly useful for their low temperature processing capability making them more coextrusion compatible with less thermally stable second polymers. Other semicrystalline polyesters suitable as birefringent polymers include, for example, polybutylene 2,6-naphthalate (PBN), polyethylene terephthalate (PET), and copolymers thereof such as those described in U.S. Pat. No. 6,449,093 B2 or U.S. Pat. App. No. 20060084780, both herein incorporated by reference in their entirety. Alternatively, syndiotactic polystyrene (sPS) is another useful birefringent polymer.

The second polymer of the multilayer optical film can be made from a variety of polymers having glass transition temperatures compatible with that of the first birefringent polymer and having a refractive index similar to the isotropic refractive index of the birefringent polymer. Examples of other polymers suitable for use in optical films and, particularly, in the second polymer include vinyl polymers and copolymers made from monomers such as vinyl naphthalenes, styrene, maleic anhydride, acrylates, and methacrylates. Examples of such polymers include polyacrylates, polymethacrylates, such as poly (methyl methacrylate) (PMMA), and isotactic or syndiotactic polystyrene. Other polymers include condensation polymers such as polysulfones, polyamides, polyurethanes, polyamic acids, and polyimides. In addition, the second polymer can be formed from homopolymers and copolymers of polyesters, polycarbonates, fluoropolymers, and polydimethylsiloxanes, and blends thereof.

Other exemplary suitable polymers, especially for use as the second polymer, include homopolymers of polymethylmethacrylate (PMMA), such as those available from Ineos Acrylics, Inc., Wilmington, Del., under the trade designations CP71 and CP80, or polyethyl methacrylate (PEMA), which has a lower glass transition temperature than PMMA. Additional second polymers include copolymers of PMMA (coPMMA), such as a coPMMA made from 75 wt % methylmethacrylate (MMA) monomers and 25 wt % ethyl acrylate (EA) monomers, (available from Ineos Acrylics, Inc., under the trade designation Perspex CP63), a coPMMA formed with MMA comonomer units and n-butyl methacrylate (nBMA) comonomer units, or a blend of PMMA and poly(vinylidene fluoride) (PVDF).

Yet other suitable polymers, especially useful as the second polymer, include polyolefin copolymers such as poly (ethylene-co-octene) (PE-PO) available from Dupont Performance Elastomers under the trade designation Engage 8200, poly (propylene-co-ethylene) (PPPE) available from Fina Oil and Chemical Co., Dallas, Tex., under the trade designation Z9470, and a copolymer of atactic polypropylene (aPP) and isotatctic polypropylene (iPP). The multilayer optical films can also include, for example in the second polymer layers, a functionalized polyolefin, such as linear low density polyethylene-g-maleic anhydride (LLDPE-g-MA) such as that available from E.I. duPont de Nemours & Co., Inc., Wilmington, Del., under the trade designation Bynel 4105.

Preferred polymer compositions suitable as the second polymer in alternating layers with the at least one birefringent polymer include PMMA, CoPMMA, polydimethyl siloxane oxamide based segmented copolymer (SPOX), fluoropolymers including homopolymers such as PVDF and copolymers such as those derived from tetrafluoroethylene, hexafluoropropylene, and vinylidene fluoride (THV), blends of PVDF/PMMA, acrylate copolymers, styrene, styrene copolymers, silicone copolymers, polycarbonate, polycarbonate copolymers, polycarbonate blends, blends of polycarbonate and styrene maleic anhydride, and cyclic-olefin copolymers.

The selection of the polymer compositions used in creating the multilayer optical film will depend upon the desired bandwidth that will be reflected onto a chosen solar cell. Higher refractive index differences between the birefringent polymer and the second polymer create more optical power thus enabling more reflective bandwidth. Alternatively, additional layers may be employed to provide more optical power. Preferred combinations of birefringent layers and second polymer layers may include, for example, the following: PET/THV, PET/SPOX, PEN/THV, PEN/SPOX, PEN/PMMA, PET/CoPMMA, PEN/CoPMMA, CoPEN/PMMA, CoPEN/SPOX, sPS/SPOX, sPS/THV, CoPEN/THV, PET/fluoroelastomers, sPS/fluoroelastomers and CoPEN/fluoroelastomers.

In one embodiment, two or more multilayer optical mirrors with different reflection bands are laminated together to broaden the reflection band. For example, a PEN/PMMA multilayer reflective mirror which reflects 98% of the light from 400 nm to 900 nm would be laminated to a PEN/PMMA multilayer reflective mirror which reflects 98% of the light from 900 nm to 1800 nm to create a broadband mirror reflecting light from 400 nm to 1800 nm. In another example, a PET/CoPMMA multilayer reflective mirror that reflects 97% of the light from 370 nm to 750 nm could be laminated to a multilayer reflective mirror which reflects 97% of the light from 700 nm to 1350 nm to create a broadband mirror reflecting light from 370 nm to 1350 nm.

The multilayer optical films are produced according to conventional processing techniques, such as those described in U.S. Pat. No 6,783,349 (Neavin et al.), herein incorporated by reference in its entirety. The multilayer optical films may also include non-optical protective boundary layers, such as for example those disclosed in U.S. Pat. No 6,783,349.

Desirable techniques for providing a multilayer optical film with a controlled spectrum include:
1) The use of an axial rod heater control of the layer thickness values of coextruded polymer layers as taught in U.S. Pat. No. 6,783,349 (Neavin et al.).
2) Timely layer thickness profile feedback during production from a layer thickness measurement tool such as e.g. an atomic force microscope (AFM), a transmission electron microscope, or a scanning electron microscope.
3) Optical modeling to generate the desired layer thickness profile.
4) Repeating axial rod adjustments based on the difference between the measured layer profile and the desired layer profile.

The basic process for layer thickness profile control involves adjustment of axial rod zone power settings based on the difference of the target layer thickness profile and the measured layer profile. The axial rod power increase needed to adjust the layer thickness values in a given feedblock zone may first be calibrated in terms of watts of heat input per nanometer of resulting thickness change of the layers generated in that heater zone. Fine control of the spectrum is possible using 24 axial rod zones for 275 layers. Once calibrated, the necessary power adjustments can be calculated once given a target profile and a measured profile. The procedure is repeated until the two profiles converge. The layer thickness profile (layer thickness values) of this UV reflector can be adjusted to be approximately a linear profile with the first (thinnest) optical layers adjusted to have about a ¼ wave optical thickness (index times physical thickness) for 340 nm light and progressing to the thickest layers which can be adjusted to be about ¼ wave thick optical thickness for 420 nm light.

### UV Protective Layer

A UV protective layer is applied onto a surface of the multilayer optical film and shields the multilayer optical film from UV radiation that may cause degradation. Solar light, in particular the ultraviolet radiation from 280 nm to 400 nm can induce degradation of plastics, which in turn results in color change and deterioration in mechanical properties. Inhibition of photo-oxidative degradation is important for outdoor applications wherein long term durability is desired. The absorption of UV light by polyethylene terephthalates, for example, starts at around 360 nm, increases markedly below 320 nm and is very pronounced at below 300 nm. Polyethylene naphthalates strongly absorb UV light in the 310-370 nm range, with an absorption tail extending to about 410 nm, and with absorption maxima occurring at 352 nm and 337 nm. Chain cleavage occurs in the presence of oxygen, and the predominant photooxidation products are carbon monodioxide, carbon dioxide, and carboxylic acids. Besides the direct photolysis of the ester groups, consideration has to be given to oxidation reactions which likewise form carbon dioxide via peroxide radicals.

The UV protective layer may shield the multilayer optical film by reflecting UV light, absorbing UV light, scattering UV light, or a combination thereof. In general, the UV protective film may include any polymer composition that is capable of withstanding UV radiation for an extended period of time while either reflecting, scattering, or absorbing UV radiation. Non-limiting examples of such polymers include PMMA, silicone thermoplastics, fluoropolymers, and their copolymers, and blends thereof. An exemplary UV protective layer comprises PMMA/PVDF blends.

A variety of optional additives may be incorporated into the UV protective layer to assist in its function of protecting the multilayer optical film. Non-limiting examples of the additives include one or more compounds selected from ultra violet absorbers, hindered amine light stabilizers, anti-oxidants, and combinations thereof.

UV stabilizers such as UV absorbers are chemical compounds which can intervene in the physical and chemical processes of photo-induced degradation. The photooxidation of polymers from UV radiation can therefore be prevented by use of a protective layer containing UV absorbers to effectively block UV light. For the purpose of the present invention, UV stabilizers suitable as light stabilizers are red shifted UV absorbers (RUVA) which absorb at least 70%, preferably 80%, particularly preferably greater than 90% of the UV light in the wavelength region from 180 nm to 400 nm. The RUVA are suitable if they are highly soluble in polymers, highly absorptive, photo-permanent and thermally stable in the temperature range from 200 to 300° C. for extrusion process to form the protective layer. The RUVA can also be highly suitable if they can be copolymerizable with monomers to form protective coating layer by UV curing, gamma ray curing, e-beam curing, or thermal curing processes.

The RUVA have enhanced spectral coverage in the long-wave UV region, enabling it to block the high wavelength UV light that can cause yellowing in polyesters. Typical UV protective layer thicknesses are from 0.5 to 15 mil (13 to 380 microns) with a RUVA loading level of 2-10%. One of the most effective RUVA is a benzotriazole compound, 5-trifluoromethyl-2-(2-hydroxy-3-alpha-cumyl-5-tert-octylphenyl)-2H-benzotriazole (sold under the trade designation CGL-0139 by ??). Other preferred benzotriazoles include 2-(2-hydroxy-3,5-di-alpha-cumylphehyl)-2H-benzotriazole, 5-chloro-2-(2-hydroxy-3-tert-butyl-5-methylphenyl)-2H-benzotiazole, 5-chloro-2-(2-hydroxy-3,5-di-tert-butylphenyl)-2H-benzotriazole, 2-(2-hydroxy-3,5-di-tert-amylphenyl)-2H-benzotriazole, 2-(2-hydroxy-3-alpha-cumyl-5-tert-octylphenyl)-2H-benzotriazole, 2-(3-tert-butyl-2-hydroxy-5-methylphenyl)-5-chloro-2Hbenzotriazole. Further preferred RUVA includes 2(-4,6-diphenyl-1-3,5-triazin-2-yl)-5-hekyloxy-phenol. Other exemplary UV absorbers include those available from Ciba Specialty Chemicals Corporation, Tarryton, N.Y., under the trade designation Tinuvin 1577, Tinuvin 900, and Tinuvin 777. In addition, the UV absorbers can be used in combination with hindered amine light stabilizers (HALS) and anti-oxidants. Exemplary HALS include those available from Ciba Specialty Chemicals Corporation, under the trade designation Chimassorb 944 and Tinuvin 123. Exemplary anti-oxidants include those obtained under the trade designations Irganox 1010 and Ultranox 626, also available from Ciba Specialty Chemicals Corporation.

In an alternative embodiment, the compliant UV protective layer is a multilayer optical film that reflects wavelengths of light from about 350 to about 400 nm, and even more preferably from 300 nm to 400 nm. The polymers that make the multilayer optical film preferably do not absorb UV light in the 300 nm to 400 nm range. Non-limiting examples include PET/THV, PMMA/THV, PET/SPOX, PMMA/SPOX, sPS/THV, sPS/SPOX, modified polyolefin copolymers (EVA) with THV, TPU/THV, and TPU/SPOX. In a preferred embodiment, Dyneon THV 220 grade and 2030 grade, from Dyneon LLC, Oakdale, Minn., are employed with PMMA for multilayer UV mirrors reflecting 300-400 nm or with PET for multilayer mirrors reflecting 350-400 nm. In general, 100 to 1000 total layers of the polymer combinations are suitable for use with the present invention.

Other additives may be included in the UV protective layer. Small particle non-pigmentary zinc oxide and titanium oxide can also be used as blocking or scattering additives in the UV protective layer. For example, nano-scale particles can be dispersed in polymer or coating substrates to minimize UV radiation degradation. The nano-scale particles are transparent to visible light while either scattering or absorbing harmful UV radiation thereby reducing damage to thermoplastics. U.S. Pat. No. 5,504,134 describes attenuation of polymer substrate degradation due to ultraviolet radiation through the use of metal oxide particles in a size range of about 0.001 micrometer to about 0.20 micrometer in diameter, and more preferably from about 0.01 to about 0.15 micrometers in diameter. U.S. Pat. No. 5,876,688 teaches a method for producing micronized zinc oxide that are small enough to be transparent when incorporated as UV blocking and/or scatterring agents in paints, coatings, finishes, plastic articles, cosmetics and the like which are well suited for use in the present invention. These fine particles such as zinc oxide and titanium oxide with particle size ranged from 10-100 nm that can attenuate UV radiation are commercially available from Kobo Products, Inc. South Plainfield, N.J. Flame retardants may also be incorporated as an additive in the UV protective layer.

In addition to adding UV absorbers, HALS, nano-scale particles, flame retardants, and anti-oxidants to the UV protective layer, the UV absorbers, HALS, nano-scale particles, flame retardants, and anti-oxidants can be added to the multilayer optical layers, and the optional durable top coat layers. Fluorescing molecules and optical brighteners can also be added to the UV protective layer, the multilayer optical layers, the optional durable top coat layer, or a combination thereof.

The thickness of the UV protective layer is dependent upon an optical density target at specific wavelengths as calculated by Beers Law. In some embodiments, the UV protective layer has an optical density greater than 3.5, 3.8, or 4 at 380 nm; greater than 1.7 at 390 nm; and greater than 0.5 at 400 nm. Those of ordinary skill in the art recognize that the optical densities typically should remain fairly constant over the extended life of the article in order to provide the intended protective function.

The UV protective layer, and any optional additives, may be selected to achieve the desired protective functions such as UV protection, ease in cleaning, and durability in the solar concentrating mirror. Those of ordinary skill in the art recognize that there are multiple means for achieving the noted objectives of the UV protective layer. For example, additives that are very soluble in certain polymers may be added to the composition. Of particular importance, is the permanence of the additives in the polymer. The additives should not degrade or migrate out of the polymer. Additionally, the thickness of the layer may be varied to achieve desired protective results. For example, thicker UV protective layers would enable the same UV absorbance level with lower concentrations of UV absorbers, and would provide more UV absorber permanence attributed to less driving force for UV absorber migration. One mechanism for detecting the change in physical characteristics is the use of the weathering cycle described in ASTM G155 and a D65 light source operated in the reflected mode. Under the noted test, and when the UV protective layer is applied to the article, the article should withstand an exposure of at least 18,700 kJ/m² at 340 nm before the b* value obtained using the CIE L*a*b* space increases by 5 or less, 4 or less, 3 or less, or 2 or less before the onset of significant cracking, peeling, delamination or haze.

### Tie Layer

An optional tie layer may be interposed between the multilayer optical film and the UV protective layer to assist in the adherence of the films and provide long term stability while the article of the present invention is exposed to outdoor elements. Non-limiting examples of tie layers include: SPOX, and CoPETs including modifications such as with functional groups sulfonic acids, PMMA/PVDF blends, modified olefins with functional comonomers such as maleic anhydride, acrylic acid, methacrylic acid or vinyl acetate. Additionally, UV or thermally curable acrylates, silicones, epoxies, siloxanes, urethane acrylates may be suitable as tie layers. The tie-layers may optionally contain UV absorbers as described above. The tie layers may optionally contain conventional plasticizers, tackifiers, or combinations thereof. The tie layer may be applied utilizing conventional film forming techniques.

### Optional Top Coat

The article may optionally include a durable top coat to assist in preventing the premature degradation of the solar concentrating mirror due to exposure to outdoor elements. The durable topcoat is generally abrasion and impact resistant and does not interfere with the primary function of reflecting a selected bandwidth of electromagnetic radiation. Durable top coat layers may include one or more of the following non-limiting examples, PMMA/PVDF blends, thermoplastic polyurethanes, curable polyurethanes, CoPET, cyclic olefin copolymers (COC's), fluoropolymers and their copolymers such as PVDF, ETFE, FEP, and THV, thermoplastic and curable acrylates, cross-linked acrylates, cross-linked urethane acrylates, cross-linked urethanes, curable or cross-linked polyepoxides, and SPOX. Strippable polypropylene copolymer skins may also be employed. Alternatively, silane silica sol copolymer hard coating can be applied as a durable top coat to improve scratch resistance. The durable top coat may contain UV absorbers, HALS, and anti-oxidants as described above.

The durable top coat provides mechanical durability to the article. Some mechanisms for measuring mechanical durability may be either impact or abrasion resistance. Taber abrasion is one test to determine a film's resistance to abrasion, and resistance to abrasion is defined as the ability of a material to withstand mechanical action such as rubbing scrapping, or erosion. According to the ASTM D1044 test method, a 500-gram load is placed on top of CS-10 abrader wheel and allowed to spin for 50 revolutions on a 4 sq. inch test specimen. The reflectivity of the sample before and after the Taber abrasion test is measured, and results are expressed by changes in % reflectivity. For the purpose of this invention, change in % reflectivity is expected to be less than 20%, preferred to be less than 10% and particularly more preferred to be less than 5%.

Other suitable tests for mechanical durability include break elongation, pencil hardness, sand blast test, and sand shaking abrasion. UV absorbers and appropriate UV stabilizers described above can be added into the top coat for stabilizing the coating as well as for protection of the substrates. The substrates coated with such a durable hard coat are thermoformable before being fully cured at an elevated temperature, and a durable hard coat can then be formed by a post curing at 80° C. for 15-30 minutes. In addition, siloxane components used as a durable top coat are hydrophobic in nature and can provide an easy clean surface function to the articles disclosed in this invention

Due to the outdoor application, weathering is also an important characteristic of the solar concentrating mirror. Accelerated weathering studies are one option for qualifying the performance of the article. Accelerated weathering studies are generally performed on films using techniques similar to those described in ASTM G-155, “Standard practice for exposing non-metallic materials in accelerated test devices that use laboratory light sources”. The noted ASTM technique is considered as a sound predictor of outdoor durability, that is, ranking materials performance correctly.

In an alternative embodiment, a reverse construction may be employed on a side of the multilayer optical film opposite the required UV protective layer. The alternative construction can provide additional functional features for specific applications of the article. For example, it may be desirable to provide an additional UV protective layer on the multilayer optical film in order to provide backside protection from UV radiation. Other potential embodiments can include carbon black or an IR absorbing layer on the side opposite the direct exposure to the sun. Another alternative embodiment may include an antireflective coating on the backside to prevent backside IR reflection. Tie layers, such as those previously disclosed, can be used in providing the alternative embodiments.

The resulting physical characteristics of the film provide enhanced properties when applied as a solar concentrating mirror for focusing specific bandwidths of electromagnetic radiation onto a solar cell. The multilayer optical film, in combination with a UV protective film of a selected thickness, may be designed to reflect a desired bandwidth of electromagnetic radiation while transmitting undesirable electromagnetic radiation. The unique capability to select multilayer optical films to match specific solar cells, while reducing radiation adverse to the solar cell, significantly enhances the operational efficiency of the solar cell. Some embodiments exhibit a reflectivity of 98% or greater of light corresponding to the absorption bandwidth of the selected solar cell.

The solar concentrating mirror may be positioned in close proximity to the solar cell to enable the desired level of reflection onto the solar cell. The article may be a stand alone application or alternatively may be applied onto a substrate to provide additional rigidity, or dimensional stability. Suitable substrates include, for example, glass sheet, polymeric sheets, and polymer fiber composites including glass fiber composites. An optional tie layer, such as those previously described, may be employed in bonding the article to the substrate. Also, optionally a UV absorber may be included in the substrate. In another alternative embodiment, the article may be thermoformed into shapes or dimensions conventionally used for solar concentrators. Additionally, the solar concentrating mirror may be reinforced, for example, by injection cladding, corrugation, or addition of ribs, foam spacer layers, or honeycomb structures to improve its dimensional stability. One exemplary reinforcing material is twin wall polycarbonate sheeting, e.g., as available as SUNLITE MULTIWALL POLYCARBONATE SHEET from Palram Americas, Inc. of Kutztown, Pa. Thermoforming is generally described in U.S. Pat. No. 6,788,463 (Merrill et al.), herein incorporated by reference in its entirety.

In another embodiment, the solar concentrating mirror could be laminated to an infra-red absorbing material such as black painted aluminum or black painted steel. Additionally, the black painted aluminum or steel could have reinforcing ribs or structures for improved dimensional stability.

### Solar Cells

Suitable solar cells include those that have been developed with a variety of materials each having a unique absorption spectra that converts solar energy into electricity. Each type of semiconductor material will have a characteristic band gap energy which causes it to absorb light most efficiently at certain wavelengths of light, or more precisely, to absorb electromagnetic radiation over a portion of the solar spectrum. Examples of materials used to make solar cells and their solar light absorption band-edge wavelengths include, but are not limited to: crystalline silicon single junction (about 400 nm to about 1150 nm), amorphous silicon single junction (about 300 nm to about 720 nm), ribbon silicon (about 350 nm to about 1150 nm), CIGS (Copper Indium Gallium Selenide) (about 350 nm to about 1100 nm), CdTe (about 400 nm to about 895 nm), GaAs multi-junction (about 350 nm to about 1750 nm). The shorter wavelength left absorption band edge of these semiconductor materials is typically between 300 nm and 400 nm. One skilled in the art understands that new materials are being developed for more efficient solar cells having their own unique longer wavelength absorption band-edge and the multilayer reflective film would have a corresponding reflective band-edge.

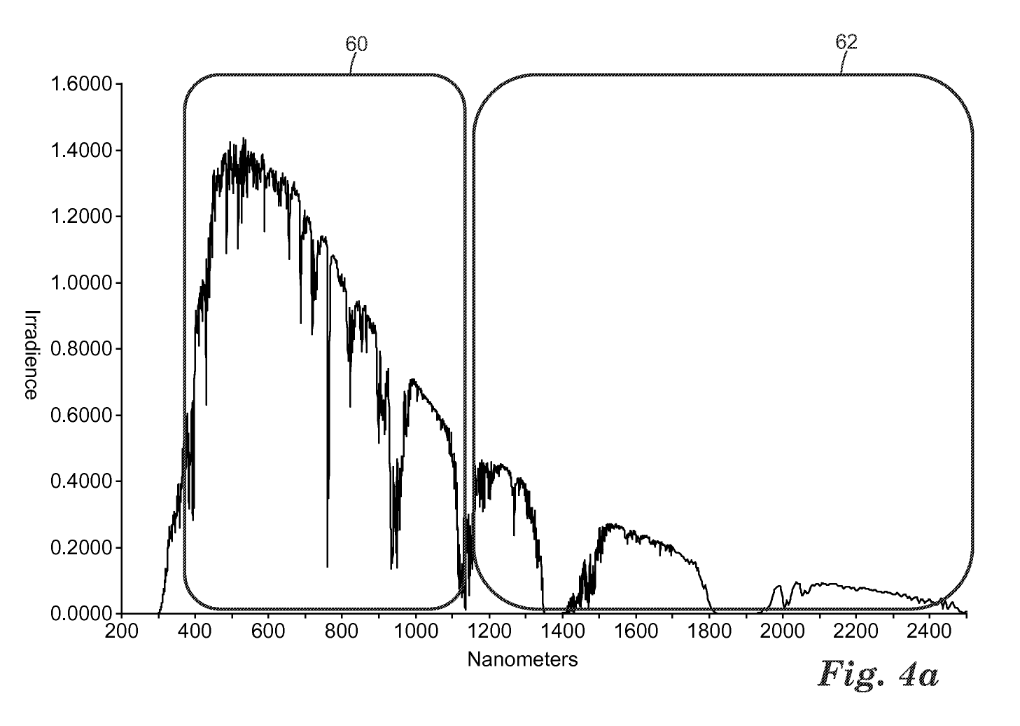

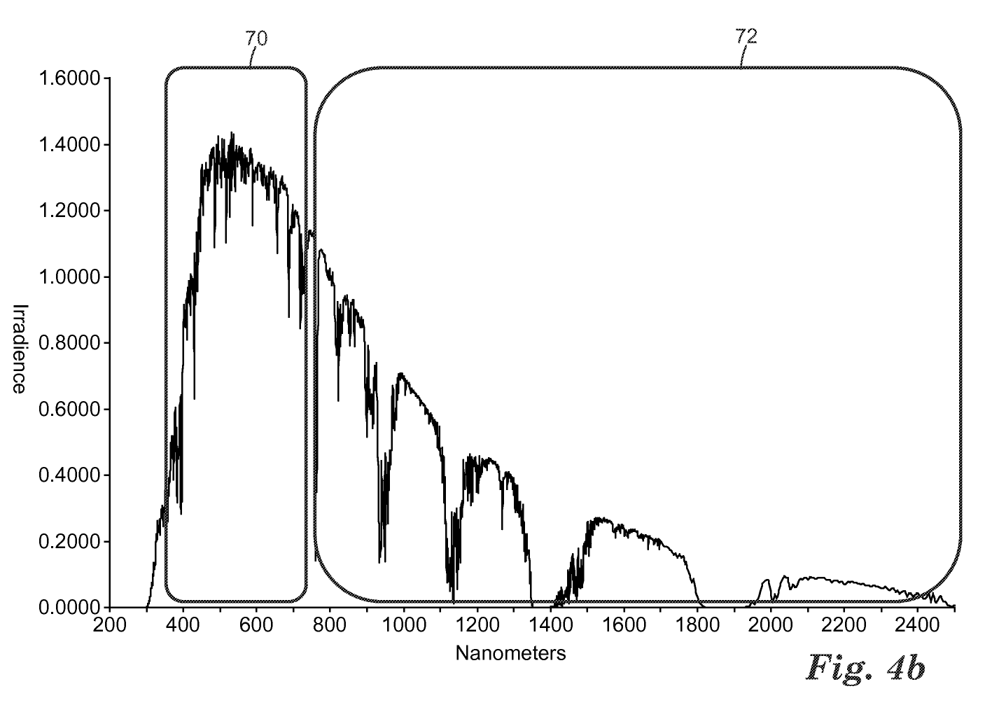

FIGS. 4a, 4b, and 4c depict potential applications of the article of the present invention in combination with specific solar cells. FIG. 4a is a graph of the solar spectrum versus absorption for a crystalline silicon single junction solar cell. FIG. 4a illustrates an operating window 60 that corresponds with the reflection of visible and near infrared electromagnetic radiation up to about 1150 nm. The far infrared region 62, greater than about 1150 nm, is not reflected. Another example using an amorphous silicon single junction is depicted in FIG. 4b. In FIG. 4b, the operating window 70 of the article of the present invention corresponds with the longer wavelength (infrared) absorption band-edge of an amorphous silicon single junction solar cell. The infrared region 72 is not reflected by the article of the present invention. FIG. 4c, illustrates the application of a concentrating mirror with a GaAs multi-junction solar cell having a longer wavelength (infrared) absorption band-edge of about 1750 nm. In FIG. 4c, the operating window 80 corresponds to the reflected electromagnetic radiation by the article of the present invention. The infrared radiation 82 is not reflected by the concentrating mirror.

As illustrated in FIGS. 4a, 4b, and 4c, the concentrating mirror, when placed in close proximity to a selected solar cell, is utilized to reflect at least a major portion of the average light across the range of wavelengths corresponding with the absorption bandwidth of the solar cell onto the solar cell. The concentrating mirror does not reflect onto the solar cell a major portion of light outside the absorption bandwidth of the solar cell. The major portion of the average light across the range of wavelengths that corresponds with the absorption bandwidth of a selected solar cell reflected by the article represents a value selected from greater than 50%, (e.g., greater than 70%, greater than 80%, greater than 90% , or even greater than 95%). In some embodiments, the article exhibits a reflectivity of 98% or greater of light corresponding to the absorption bandwidth of the selected solar cell. Electromagnetic radiation outside the absorption bandwidth of the solar cell is transmitted or absorbed by the concentrating mirror. The light across the range of wavelengths that corresponds with the absorption bandwidth of the solar cell is concentrated onto the solar cell by an amount greater than one (e.g., at least 1.5, 2, 3, 5, 10, 20, greater than 50, or greater than 100, up to about 800 or 1000). For example, the light may be concentrated onto the solar cell by an amount in a range from 1.1 to about 5. A concentrating mirror in combination with a crystalline silicon single junction cell typically will reflect light from about 400 nm to about 1150 or 1200 nm with at least a major portion of light greater than 1150 or 1200 nm not reflected. A concentrating mirror in combination with a GaAs multi-junction cell typically will reflect light from about 350 nm to about 1750 nm with at least a major portion of light greater than 1750 nm not reflected. A concentrating mirror in combination with an amorphous silicon single junction cell typically will reflect light from about 300 to about 720 nm with at least a major portion of light greater than 720 nm not reflected. A concentrating mirror in combination with a ribbon silicon cell typically will reflect light from about 400 to about 1150 nm with at least a major portion of light greater than 1150 nm not reflected. A concentrating mirror in combination with a copper indium gallium selenide cell typically will reflect light from about 350 to about 1100 nm with at least a major portion of light greater than 1100 nm not reflected. A concentrating mirror in combination with a cadmium telluride cell typically will reflect light from about 400 to about 895 nm with at least a major portion of light greater than 895 nm not reflected. In some embodiments of any of the concentrating mirrors disclosed herein, the infra-red light that is not reflected is transmitted.

The concentrating mirrors of the present invention enhance the efficiency of solar cells due to (i) a significant reduction of a non-selected bandwidth that in effect minimizes overheating of solar cell; (ii) an increased power output obtained with polymeric mirrors that result in lower costs per produced energy ($/Watt); and (iii) increased durability due to UV protection and abrasion resistance.

Further enhancements in the solar cell power output may be achieved when anti-reflective surface structured films or coatings are applied to the front surface of the solar cell in combination with the solar collection device disclosed herein. Surface structures in the films or coating typically change the angle of incidence of light such that it enters the polymer and solar cell beyond the critical angle and is internally reflected, leading to more absorption by the solar cell. Such surface structures can be in the shape, for example, of linear prisms, pyramids, cones, or columnar structures. For prisms, typically the apex angle of the prisms is less than 90 degrees (e.g., less than 60 degrees). The refractive index of the surface structured film or coating is typically less than 1.55 (e.g., less than 1.50). These anti-reflective surface structured films or coatings can be made durable and easily cleanable with the use of inherently UV stable and hydrophobic or hydrophilic materials. Durability can be enhanced with the addition of inorganic nano-particles.

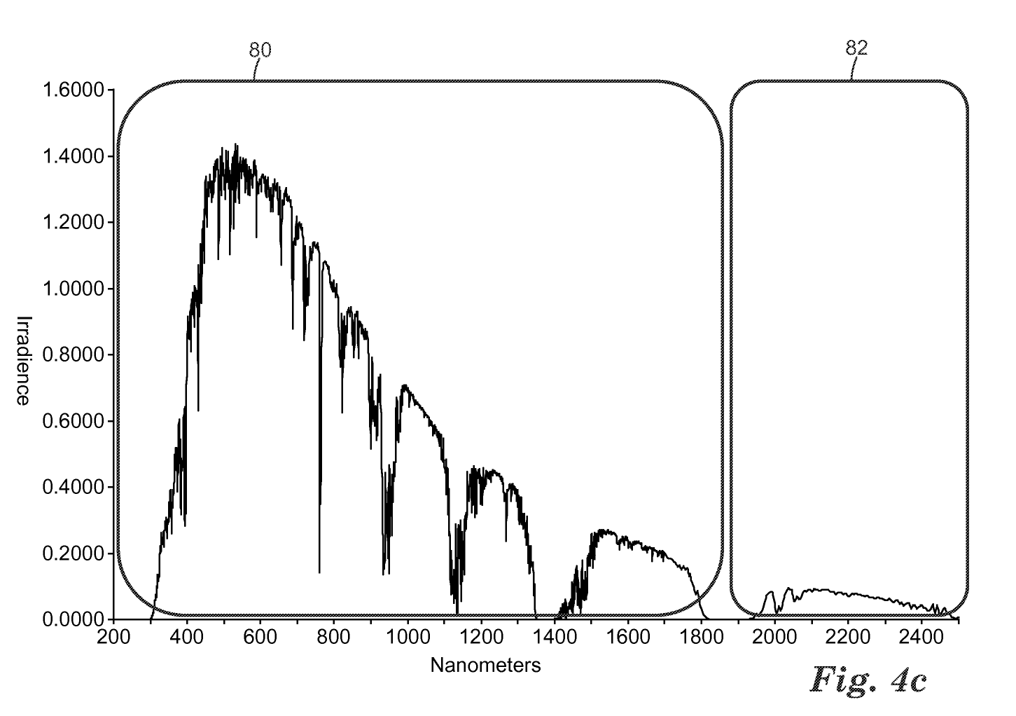

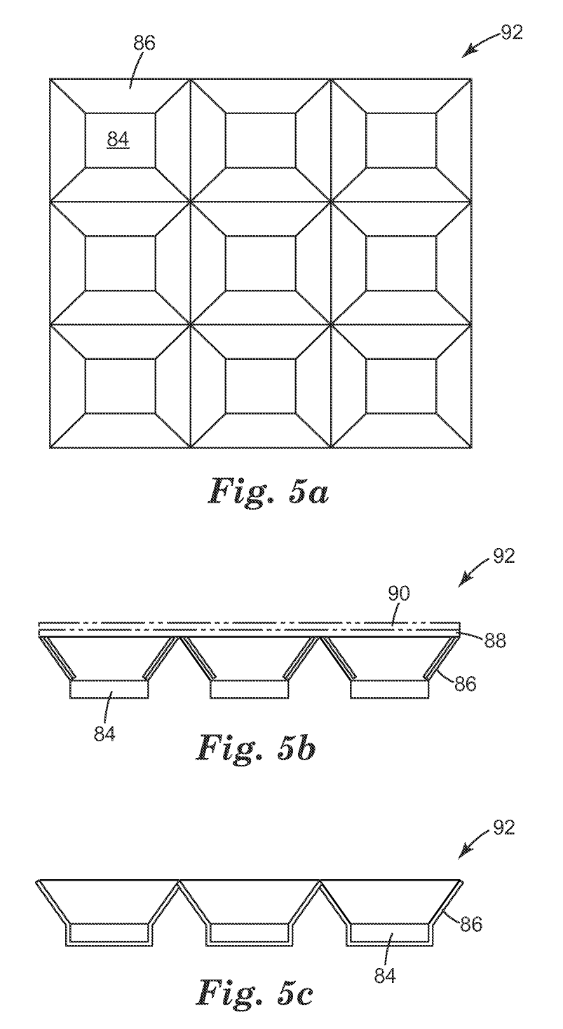

FIGS. 5a, 5b and 5c illustrate an application of the concentrating mirror and an array of solar cells. In FIG. 5a, solar cells 84 are placed into an array 92 with multiple concentrating mirrors 86 positioned in close proximity to the solar cells to reflect to reflect onto the solar cell at least a major portion of the average light across the range of wavelengths corresponding with the absorption bandwidth of the solar cell. Light outside of the desired bandwidth is not reflected by the concentrating mirror. In FIG. 5b, the array of solar cells 84 and the concentrating mirror 86 are shown in a schematic cross sectional view with an optional ultraviolet mirror 88 and an optional infrared mirror 90. FIG. 5c depicts an alternative embodiment indicating that the concentrating mirror 86 is thermoformed around the solar cells 84. In this embodiment, the concentrating mirror 86 reflects from the sides and back of the solar cell 84 to further enhance the efficiency of the system.

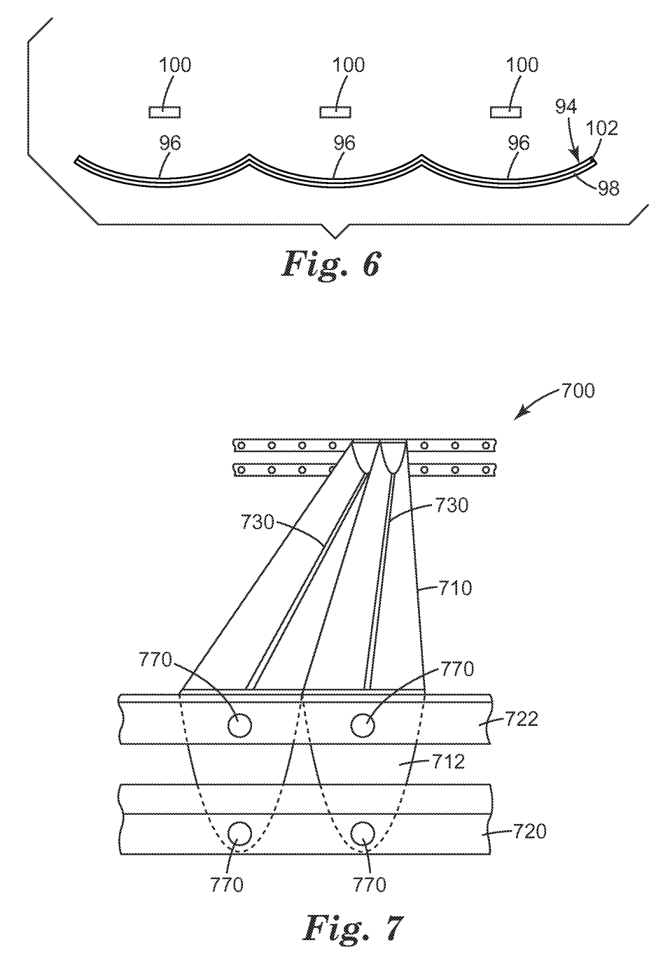

Those of ordinary skill in the art recognize that the application of the solar concentrating mirror of the present invention could occur in various arrangements and arrays in combination with solar cells. FIG. 6 is a solar concentrating mirror 94 comprising an array of multiple curved surface mirrors 96 comprising continuous multilayer mirror 98 laminated to continuous UV protective layer 102 that concentrate solar light onto solar cells 100.

The solar concentrating mirror, in combination with a solar cell, may be further applied with other conventional solar collection devices to further enhance the application of the solar concentrating mirror. For example, thermal transfer devices may be applied to either collect energy from the solar cell or dissipate heat from the solar cell. Conventional thermal heat sinks include thermally conductive materials that include ribs, pins or fins to enhance the surface area for heat transfer. The thermally conductive materials include metals or polymers modified with fillers to improve the thermal conductivity of the polymer. Thermally conductive adhesives (e.g., a thermally conductive adhesive available from 3M Company under the trade designation 3M TC-2810) may be used to attach solar cells to thermal transfer devices. Additionally, conventional heat transfer fluids, such as water, oils or fluoroinert heat transfer fluids may be employed as thermal transfer devices.

In some embodiments, an array of solar cells, in combination with the concentrating mirror, can be placed on conventional celestial tracking devices. For example, in some embodiments of a solar collection device disclosed herein, the one or more solar cells or the at least one solar concentrating mirror is connected to one or more celestial tracking mechanisms. The one or more solar cells or the at least one solar concentrating mirror may be pivotally mounted on a frame. In some embodiments, both the one or more solar cells and the at least one solar concentrating mirror are pivotally mounted on a frame. The pivotally mounted components may pivot, for example, in one direction or in two directions. In some embodiments, the one or more solar cells is stationary.

One embodiment of a solar collection device comprising a celestial tracking mechanism is illustrated in FIG. 7. FIG. 7 shows a solar collection device 700 comprising solar concentrating mirrors formed as troughs 710 with the solar cell 730 placed at the axis. Two rods 770 extending outside the end pieces 712 of a trough 710 are used to connect the trough to a frame 720 and a crossbar 722, respectively, at each end of the assembly. The crossbar 722 can be connected to a driving mechanism. With a plurality of troughs 710 being pivotally positioned in a pair of parallel stationary frames, as shown in FIG. 7, the crossbars 722 to which each trough 710 is attached can, in some embodiments, simultaneously pivot all of the troughs about their axes. Thus, the orientation of all the troughs 710 can be collectively adjusted to follow the sun movement in unison. Although FIG. 7 shows two crossbars 722, one on each side of the trough 710, it is possible to use only one crossbar. In some embodiments of solar collection devices 700 shown in FIG. 7, the trough 710 is aligned in the east-west direction with a rotational freedom typically not less than 10 degrees, 15 degrees, 20 degrees, or 25 degrees, for example, for adjustments to track the sun through seasonal variations (i.e., through the different paths between equinox and solstice). When the solar cell 730 is incorporated into a linear compound parabolic concentrator trough 710 tilted toward the south, the incident solar irradiance enters within the acceptance angle of the compound parabolic concentrator. The aperture of the parabola determines how often the position of the trough 710 must be changed (e.g., hourly, daily, or less frequently). In some embodiments of solar collection devices 700 shown in FIG. 7, the solar cell is aligned in the north-south direction, and the rotational freedom is typically not less than 90 degrees, 120 degrees, 160 degrees, or 180 degrees, for example, for tracking adjustments following the sun as it moves across the sky throughout the day. In some of these embodiments, the frame can be mounted, for example, to a back board (not shown) for the solar collection device, which back board may comprise a mechanism for adjusting tilt to track the sun through seasonal variations. Although troughs 710 shown in FIG. 7, have parabolic shapes, other shapes may be used (e.g., hyperbolic, elliptical, tubular, or triangular). Additional celestial tracking mechanisms which allow the solar concentrating mirror and/or the solar cell to pivot in two directions and which may be useful for solar collection devices disclosed herein are described in US Pat. App. Pub. No. 2007/0251569 (Shan et al.).

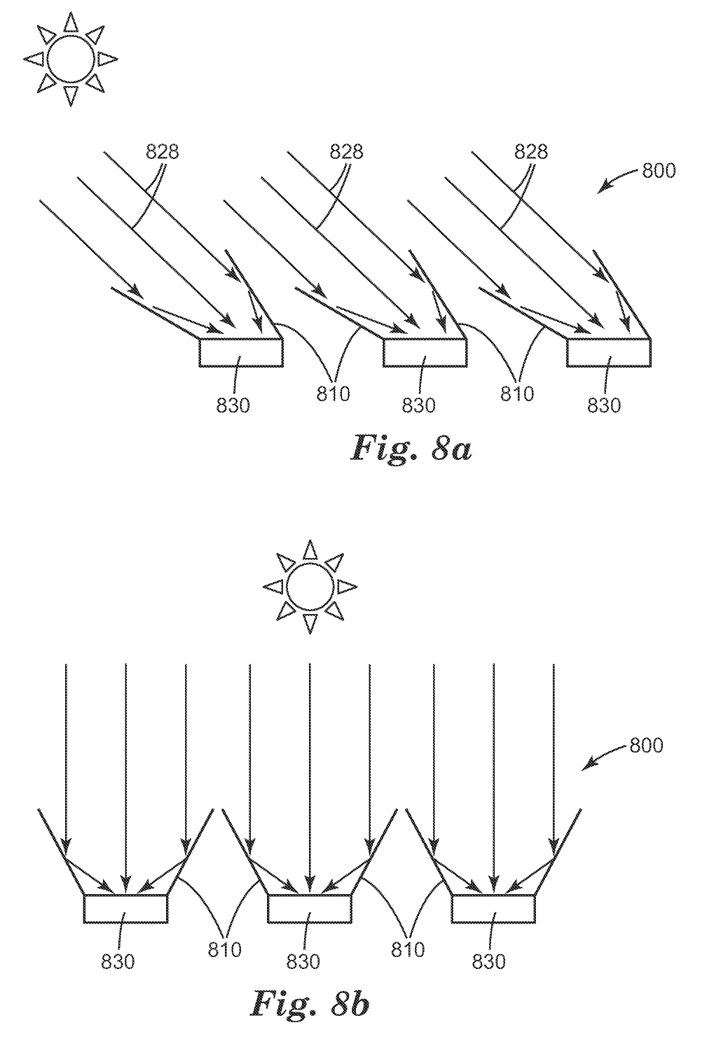

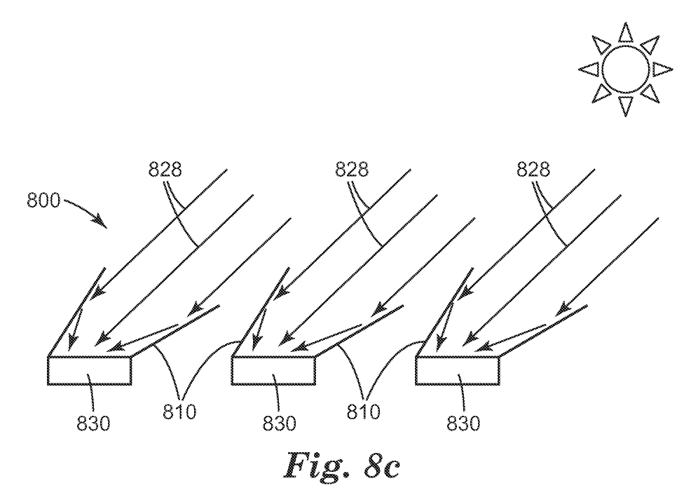

Another embodiment of a solar collection device comprising a celestial tracking mechanism is illustrated in FIGS. 8a, 8b, and 8c. In this embodiment, array 800 comprises solar cells 830 and louvers 810 comprising the solar concentrating mirror according to any of the embodiments disclosed herein pivotally mounted adjacent the solar cells. A louver can comprise, for example, the solar concentrating mirror disclosed herein applied onto a substrate (e.g., a glass sheet, polymeric sheet, a structured polymer sheet comprising a corrugated laminate or a multi-wall polymer sheet construction, a polymer fiber composite, or a black painted metal) or a free-standing mirror. In some embodiments, the louver comprises a solar concentrating mirror disclosed herein laminated to a polymer sheet (e.g., PMMA). The louver may be directly attached to either side of the solar cell (e.g., with hinges) as shown in FIG. 8a, 8b, or 8c, or the louver may be pivotally mounted on a frame that also holds the solar cell. In some embodiments, there is at least one louver pivotally mounted adjacent each solar cell. In some embodiments, two louvers are adjacent (in some embodiments, hinged to) each solar cell.

In FIGS. 8a, 8b, and 8c, the louvers 810 are oriented toward the morning, mid-day, and evening sun, respectively. The louvers 810 track the sun and enable increased capture of sunlight 828 by solar cells 830. As a result, typically fewer photovoltaic cells 830 are needed in an array 800. The array 800 shown in FIGS. 8a and 8c may be especially effective at increasing the capture of sunlight in the mornings and evenings. The louvers can move independently with rotational freedom typically not less than 90 degrees, 120 degrees, 160 degrees, or 180 degrees, for example, for tracking adjustments following the sun as it moves across the sky throughout the day. Optionally, the array 800 can be mounted, for example, to one or more back boards (not shown), which may comprise a mechanism for adjusting tilt to track the sun through seasonal variations. The louvers may be planar, substantially planar, or curved in shape.

Solar cell arrays 800 with louver solar trackers 810 can be made with a lower profile and lighter weight than typical pole mount trackers. In some embodiments of array 800, photovoltaic cells having widths of 1 inch (2.54 cm) or less can be used to minimize the depth profile of the array. Arrays could also be designed with larger photovoltaic cells (e.g., widths of 6-inch (15 cm), 12-inch (30.5 cm), 21-inch (53 cm), or higher). Thus, the arrays 800 can be designed to fit a number of applications including use on roof tops. In embodiments wherein the solar cells 830 are stationary and the louvers 810 are pivotally mounted, the portion of the electronics connected to the solar cells can also be stationary, which may be advantageous over tracking systems which require movement of the solar cells.

In some embodiments, when louvers 810 comprise IR transmissive solar concentrating mirrors with a low concentration ratio (e.g., less than 10, up to 5, up to 3, up to 2.5, or in a range from 1.1 to 5) the need for expensive and heavy thermal management devices for photovoltaic cells may be reduced. Solar concentration can be adjusted, for example, with the size of the mirror relative to the photovoltaic cell and the mirror's angle relative to the photovoltaic cell to optimize the solar concentration ratio for a desired geographic location. Furthermore, closed loop control systems may be used to adjust the louver position to minimize the concentration ratio such that the photovoltaic cell is maintained below 85° C.

Movement of troughs 710 shown in FIG. 7 or louvers 810 shown in FIGS. 8a, 8b, and 8c can be controlled by a number of mechanisms (e.g., piston driven levers, screw driven levers or gears, pulley driven cables, and cam systems). Software can also be integrated with the tracking mechanism based on GPS coordinates to optimize the position of the mirrors.

### EXAMPLES

### Comparative Example 1

A multilayer optical film was made with first optical layers created from polyethylenenaphthalate (PEN) made by the 3M Company, St. Paul, Minn. and second optical layers created from polymethylmethacrylate (PMMA) from Arkema Inc. Philadelphia, Pa. and sold under the trade designation as VO44 Acrylic Resin. PEN and PMMA were coextruded through a multilayer polymer melt manifold to create a multilayer melt stream having 530 alternating first and second optical layers. In addition to the first and second optical layers, a pair of non-optical layers also comprised of PEN were coextruded as protective skin layers on either side of the optical layer stack. This multilayer coextruded melt stream was cast onto a chilled roll at 22 meters per minute creating a multilayer cast web approximately 1075 microns (43 mils) thick. The multilayer cast web was then heated in a tenter oven at 145° C. for 10 seconds prior to being biaxially oriented to a draw ratio of 3.8×3.8. The oriented multilayer film was further heated to 225° C. for 10 seconds to increase crystallinity of the PEN layers. Reflectivity of this multilayer visible mirror film was measured with a LAMBDA 950 spectrophotometer (obtained from Perkin-Elmer, Inc., Waltham, Mass.) to have an average reflectivity of 98.5% over a bandwidth of 390-850 nm. After 3000 hours exposure to a Xenon arc lamp weatherometer according to ASTM G155-05a, a change in b* of 5 units was measured with the LAMBDA 950 spectrophotometer.

### Example 1

A multilayer optical film was made with birefringent layers created from PEN and second polymer layers created from PMMA using the same PEN and PMMA materials from Comparative Example 1. The PEN and PMMA were coextruded through a multilayer polymer melt manifold to create a multilayer melt stream having 275 alternating birefringent layers and second polymer layers. In addition, a pair of non-optical layers also comprised of PEN were coextruded as protective skin layers on either side of the optical layer stack. This multilayer coextruded melt stream was cast onto a chilled roll at 22 meters per minute creating a multilayer cast web approximately 725 microns (29 mils) thick. The multilayer cast web was then heated in a tenter oven at 145° C. for 10 seconds prior to being biaxially oriented to a draw ratio of 3.8×3.8. The oriented multilayer film was further heated to 225° C. for 10 seconds to increase crystallinity of the PEN layers. Reflectivity of this multilayer visible mirror film was measured with the LAMBDA 950 spectrophotometer resulting in an average reflectivity of 98.5% over a bandwidth of 400-1000 nm. PMMA, (VO44 Acrylic Resin) from Arkema Inc. Philadelphia, Pa., which was extrusion compounded with 5 wt. % UV-absorber obtained under the trade designation TINUVIN 1577 and 0.15 wt. % hindered amine light stabilizer obtained under the trade designation CHIMASSORB 944, both from CIBA Specialty Chemicals Corp, Tarryton, N.Y. (PMMA-UVA/HALS), and an adhesive tie-layer sold by E.I. duPont de Nemours & Co., Inc., Wilmington, Del., under the trade designation BYNEL E418, were coextrusion coated onto a multilayer mirror film made as described above and simultaneously directed into a nip under a pressure of 893 kg/m (50 pounds per lineal inch) against a casting tool having a mirror finish surface at a temperature of 90° F. (32° C.), at a casting line speed of 0.38 meters/second (75 feet per minute). The coextrusion coated layers have a total thickness of 254 microns (10 mil) with skin tie-layer thickness ratio of 20:1. The same materials were coextrusion coated onto the opposing surface of the multilayer visible mirror film. The UV absorption band edge of this extrusion coat has 50% transmission at 410 nm and absorbance of 3.45 at 380 nm. Change in b* was measured to be less than 1.0 after 3000 hours exposure to a Xenon arc lamp weatherometer according to ASTM G155-05a.

### Example 2

A multilayer reflective mirror can be made with birefringent layers created from PEN and second polymer layers created from polyoxamide silicone (SPOX) available from 3M Company, St. Paul, Minn. PEN and SPOX layers are coextruded through a multilayer polymer melt manifold to create a multilayer melt stream having 550 alternating first and second optical layers. In addition to the birefringent layers and second polymer layers, a pair of non-optical layers also comprised of PEN can be coextruded as protective skin layers on either side of the optical layer stack. This multilayer coextruded melt stream can be cast onto a chilled roll at 22 meters per minute creating a multilayer cast web approximately 1400 microns(55 mils) thick. The multilayer cast web can then be heated in a tenter oven at 145° C. for 10 seconds prior to being biaxially oriented to a draw ratio of 3.8×3.8. The oriented multilayer film can be further heated to 225° C. for 10 seconds to increase crystallinity of the PEN layers. Reflectivity of this multilayer visible mirror film can be measured with the LAMBDA 950 spectrophotometer and is predicted to have an average reflectivity of 98.9% over a bandwidth of 390-1750 nm. PMMA-UVA/HALS, which can be prepared as described in Example 1, can be coextrusion coated onto a multilayer mirror film made as described above and simultaneously directed into a nip under a pressure of 893 kg/m (50 pounds per lineal inch) against a casting tool having a mirror finish surface at a temperature of 90° F. (32° C.), at a casting line speed of 0.38 meters/second (75 feet per minute). The coextrusion coated layers will have a total thickness of 254 microns (10 mil) with skin tie-layer thickness ratio of 20:1. The same materials can be coextrusion coated onto the opposing surface of the multilayer visible mirror film. The UV absorption band edge of this extrusion coat is predicted to have a 50% transmission at 410 nm and absorbance of 3.45 at 380 nm. Change in b* is expected to be less than 2.0 after 3000 hours exposure to a Xenon arc lamp weatherometer according to ASTM G155-05a.

### Example 3

A multilayer reflective mirror can be made with birefringent layers created from PET and second polymer layers created from SPOX, both available from the 3M Company. PET and SPOX can be coextruded through a multilayer polymer melt manifold to create a multilayer melt stream having 550 alternating birefringent layers and second polymer layers. In addition, a pair of non-optical layers also comprised of PET can be coextruded as protective skin layers on either side of the optical layer stack. This multilayer coextruded melt stream can be cast onto a chilled roll at 22 meters per minute creating a multilayer cast web approximately 1400 microns (55 mils) thick. The multilayer cast web can then be heated in a tenter oven at 95° C. for 10 seconds prior to being biaxially oriented to a draw ratio of 3.8×3.8. The oriented multilayer film can be further heated to 225° C. for 10 seconds to increase crystallinity of the PET layers. Reflectivity of this multilayer visible mirror film can be measured with the LAMBDA 950 spectrophotometer and is predicted to have an average reflectivity of 98.4% over a bandwidth of 390-1200 nm. A PMMA-UVA/HALS composition, which can be prepared as described in Example 1, and an adhesive tie-layer as described in Example 1 can be coextrusion coated onto a multilayer mirror film made as described above and simultaneously directed into a nip under a pressure of 893 kg/m (50 pounds per lineal inch) against a casting tool having a mirror finish surface at a temperature of 90° F. (32° C.), at a casting line speed of 0.38 meters/second (75 feet per minute). The coextrusion coated layers will have a total thickness of 254 um (10 mil) with skin tie-layer thickness ratio of 20:1. The same materials can be coextrusion coated onto the opposing surface of the multilayer visible mirror film. The UV absorption band edge of this extrusion coat is predicted to have 50% transmission at 410 nm and absorbance of 3.45 at 380 nm. No change in b* is expected after 3000 hrs exposure to a Xenon arc lamp weatherometer according to ASTM G155.

### Example 4

A multilayer reflective mirror can be made with birefringent layers created from PEN and second polymer layers created from a fluoropolymer available under the trade designation THV2030 from Dyneon LLC, Oakdale, Minn. PEN and the fluoropolymer can be coextruded through a multilayer polymer melt manifold to create a multilayer melt stream having 550 alternating first birefringent and second polymer layers. In addition to the birefringent layers and second polymer layers, a pair of non-optical layers also comprised of PEN can be coextruded as protective skin layers on either side of the optical layer stack. This multilayer coextruded melt stream can be cast onto a chilled roll at 22 meters per minute creating a multilayer cast web approximately 1400 microns (55 mils) thick. The multilayer cast web can then be heated in a tenter oven at 145° C. for 10 seconds prior to being biaxially oriented to a draw ratio of 3.8×3.8. The oriented multilayer film can be further heated to 225° C. for 10 seconds to increase crystallinity of the PEN layers. Reflectivity of this multilayer visible mirror film can be measured with the LAMBDA 950 spectrophotometer and is predicted to have an average reflectivity of 99.5% over a bandwidth of 390-1750 nm. A PMMA-UVA/HALS composition, which can be prepared as described in Example 1, and an adhesive tie-layer as described in Example 1 can be coextrusion coated onto a multilayer mirror film made as described above and simultaneously directed into a nip under a pressure of 893 kg/m (50 pounds per lineal inch) against a casting tool having a mirror finish surface at a temperature of 90° F. (32° C.), at a casting line speed of 0.38 meters/second (75 feet per minute). The coextrusion coated layers will have a total thickness of 254 microns (10 mil) with skin tie-layer thickness ratio of 20:1. The same materials can be coextrusion coated onto the opposing surface of the multilayer visible mirror film. The UV absorption band edge of this extrusion coat are predicted to have 50% transmission at 410 nm and absorbance of 3.45 at 380 nm. The expected change in b* is measured to be less than 2.0 after 3000 hours exposure to a Xenon arc lamp weatherometer according to ASTM G155.

### Example 5

A multilayer reflective mirror can be made with birefringent polymer layers created from PET and second polymer layers created from fluoropolymer THV2030 from Dyneon LLC. PET and the fluoropolymer can be coextruded through a multilayer polymer melt manifold to create a multilayer melt stream having 550 alternating first and second polymer layers. In addition to the birefringent layers and second polymer layers, a pair of non-optical layers also comprised of PET can be coextruded as protective skin layers on either side of the optical layer stack. This multilayer coextruded melt stream can be cast onto a chilled roll at 22 meters per minute creating a multilayer cast web approximately 1400 microns (55 mils) thick. The multilayer cast web can then be heated in a tenter oven at 95° C. for 10 seconds prior to being biaxially oriented to a draw ratio of 3.8×3.8. The oriented multilayer film can be further heated to 225° C. for 10 seconds to increase crystallinity of the PET layers. Reflectivity of this multilayer visible mirror film can be measured with the LAMBDA 950 spectrophotometer and is predicted to have an average reflectivity of 99% over a bandwidth of 390-1200 nm. A PMMA-UVA/HALS composition, prepared as described in Example 1, and an adhesive tie-layer prepared as described in Example 1 can be coextrusion coated onto a multilayer mirror film made as described above and simultaneously directed into a nip under a pressure of 893 kg/m (50 pounds per lineal inch) against a casting tool having a mirror finish surface at a temperature of 90° F. (32° C.), at a casting line speed of 0.38 meters/second (75 feet per minute). The coextrusion coated layers will have a total thickness of 254 microns (10 mil) with skin tie-layer thickness ratio of 20:1. The same materials can be coextrusion coated onto the opposing surface of the multilayer visible mirror film. The UV absorption band edge of this extrusion coat is predicted to have 50% transmission at 410 nm and absorbance of 3.45 at 380 nm. No change in b* is expected after 3000 hours exposure to a Xenon arc lamp weatherometer according to ASTM G155.

### Example 6

An article resulting from any of the Examples 2-5 can be laminated to or coextruded with a multilayer UV mirror made with UV transparent polymers such as PMMA and THV. This multilayer UV reflective mirror can be made with first optical layers created from PMMA and second polymer layers created from fluoropolymer THV2030. PMMA and fluoropolymer THV2030 can be coextruded through a multilayer polymer melt manifold to create a multilayer melt stream having 150 alternating first and second polymer layers. Additionally, a pair of non-optical layers also comprised of PMMA can be coextruded as protective skin layers on either side of the optical layer stack. These PMMA skins layers can be extrusion compounded with 2 wt. % of a—absorber obtained under the trade designation TINUVIN 405. This multilayer coextruded melt stream can be cast onto a chilled roll at 22 meters per minute creating a multilayer cast web approximately 300 microns (12 mils) thick. The multilayer cast web is then heated in a tenter oven at 135° C. for 10 seconds prior to being biaxially oriented to a draw ratio of 3.8×3.8. Reflectivity of this multilayer UV mirror film can be measured with the LAMBDA 950 spectrophotometer and is predicted to have an average reflectivity of 95% over a bandwidth of 350-420 nm.

### Example 7

A durable mirror as described in any of Example 2-6 can be additionally coated with a thermally cured siloxane, such as a silica-filled methylpolysiloxane polymer obtained under the trade designation PERMA-NEW 6000 from California Hardcoat Co., Chula Vista, Calif., The thermally cured siloxane can be applied to acrylic substrates by a Meyer rod with a coating thickness about 3.5-6.5 microns. The coating can be first air-dried at room temperature for few minutes, and then further cured in a conventional oven for 15-30 minutes at 80° C. A resulting thermally cured coated sample can be tested by sand shaking abrasion. After the sample is abraded by sand shaking for 60 minutes with silica sands, haze of the sample can be measured. Expected results will indicate a haze as low as less then 1%. This form of durable top coat typically will have better abrasion/scratch resistance than PMMA as measured with a Taber abrasion test.

### Example 8

A durable solar concentrating mirror as described in Example 1 was preheated at 400° F. for 35 seconds and then vacuum thermoformed to a 4-inch diameter parabolic mold having a 6-inch radius of curvature. The thermoformed durable mirror was rigid and maintained the thermoformed shape at 85° C. The parabolic multilayer mirror is capable of concentrating greater than 100 times the sun's radiation onto a high efficiency triple junction GaAs photovoltaic cell.

### Example 9

Durable mirrors as described in Example 1 were attached to a multicrystalline silicon photovoltaic module obtained under the trade designation SHARP 80W, which was comparable to that depicted in FIG. 2. The durable mirrors had the same dimensions (same surface area) as the solar cell, and were attached at a 55 degree angle from the surface of the solar cell module. When faced normal to the Sun, the solar cell produced 65% more power than without the durable mirrors attached, and the temperature increase measured on the backside of the solar cell was less than 10° C. higher than without the durable mirror solar concentrators. With the sun at a 30 degree angle from the surface of the solar cell, and one durable mirror also at a 30 degree angle from the surface of the solar cell, and the other durable mirror adjusted parallel to the surface of the solar cell, the solar cell produced 95% more power than without the durable mirrors attached, and the temperature increased measured on the backside of the solar cell was less than 15° C. higher than without the durable mirror concentrators.

### Example 10

The visible mirror film of Example 1 was laminated to a 0.25″ thick sheet of PMMA obtained from Arkema, Inc. under the trade designation PLEXIGLAS VO44 attached to the sides of an 80 watt crystalline silicon photovoltaic module (obtained under the trade designation SHARP 80W) with added hinges which allowed tracking of the sun as shown in FIGS. 8a-c.

Photovoltaic module power output was measured with a handheld voltage/current meter and calculated by multiplying open circuit voltage with closed loop current, and then multiplication again by a fill factor of 0.75, with the assumption that the fill factor was not changed by the concentrating mirrors. Temperature measurements were made both by taping multiple thermocouples to the backside of the PV module, and with the use of an infra-red pyrometer. Power measurements were made for several days in fall of 2008 in Scandia, Minn., USA which is in a Northern latitude and has a temperate climate. Considerable variability was observed when any clouds or haze occurred in the sky so averaging of the data was done. Power measurements were also made on a control photovoltaic module that was not attached to concentrating mirrors. Power measurement results are shown in Table 1, below. The temperatures of the photovoltaic modules did not exceed 85° C.

TABLE 1

| | Control | Example 10 | |
|---|---|---|---|
| Time of Day | *Power(watts) | *Power(watts) | % increase |
| 9 AM | 52.3 | 99.0 | 89.3 |
| 10 AM | 56.3 | 101.7 | 80.8 |
| 11 AM | 73.5 | 131.9 | 79.5 |
| 12 PM | 85.8 | 142.3 | 65.8 |
| 1 PM | 90.3 | 122.4 | 35.6 |
| 2 PM | 84.3 | 136.8 | 62.3 |
| 3 PM | 74.4 | 135.7 | 82.4 |

*assumes fill factor of .75

### Example 11

### Film 1

A UV-VIS reflective multilayer optical film was made with first optical layers created from polyethylene terephthalate available as EASTAPAK 7452 from Eastman Chemical of Kingsport, Tenn., (PET1) and second optical layers created from a copolymer of 75 weight percent methyl methacrylate and 25 weight percent ethyl acrylate (available from Ineos Acrylics, Inc. of Memphis, Tenn., as PERSPEX CP63) (CoPMMA1). The PET1 and CoPMMA1 were coextruded through a multilayer polymer melt manifold to form a stack of 550 optical layers. The layer thickness profile (layer thickness values) of this UV reflector was adjusted to be approximately a linear profile with the first (thinnest) optical layers adjusted to have about a ¼ wave optical thickness (index times physical thickness) for 370 nm light and progressing to the thickest layers which were adjusted to be about ¼ wave thick optical thickness for 800 nm light. Layer thickness profiles of such films were adjusted to provide for improved spectral characteristics using the axial rod apparatus taught in U.S. Pat. No. 6,783,349 (Neavin et al.) combined with layer profile information obtained with microscopic techniques.

In addition to these optical layers, non-optical protective skin layers of PET1 (260 micrometers thickness each) were coextruded on either side of the optical stack. This multilayer coextruded melt stream was cast onto a chilled roll at 5.4 meters per minute creating a multilayer cast web approximately 1100 micrometers (43.9 mils) thick. The multilayer cast web was then preheated for about 10 seconds at 95° C. and uniaxially oriented in the machine directon at a draw ratio of 3.3:1. The multilayer cast web was then heated in a tenter oven at 95° C. for about 10 seconds prior to being uniaxially oriented in the transverse direction to a draw ratio of 3.5:1. The oriented multilayer film was further heated at 225° C. for 10 seconds to increase crystallinity of the PET1 layers. The UV-reflective multilayer optical film (Film 1) was measured with a spectrophotometer (LAMBDA 950 UV/VIS/NIR SPECTROPHOTOMETER from Perkin-Elmer, Inc. of Waltham, Mass.) to have an average reflectivity of 96.8 percent over a bandwidth of 370-800 nm.

### Film 2

A near infra-red reflective multilayer optical film was made with first optical layers created from PET1 and second optical layers created from CoPMMA1. The PET1 and CoPMMA1 were coextruded through a multilayer polymer melt manifold to form a stack of 550 optical layers. The layer thickness profile (layer thickness values) of this near infra-red reflector was adjusted to be approximately a linear profile with the first (thinnest) optical layers adjusted to have about a ¼ wave optical thickness (index times physical thickness) for 750 nm light and progressing to the thickest layers which were adjusted to be about ¼ wave thick optical thickness for 1350 nm light. Layer thickness profiles of such films were adjusted to provide for improved spectral characteristics using the axial rod apparatus taught in U.S. Pat. No. 6,783,349 (Neavin et al.) combined with layer profile information obtained with microscopic techniques.

In addition to these optical layers, non-optical protective skin layers of PET1 (260 micrometers thickness each) were coextruded on either side of the optical stack. This multilayer coextruded melt stream was cast onto a chilled roll at 3.23 meters per minute creating a multilayer cast web approximately 1800 micrometers (73 mils) thick. The multilayer cast web was then preheated for about 10 seconds at 95° C. and uniaxially oriented in the machine directon at a draw ratio of 3.3:1. The multilayer cast web was then heated in a tenter oven at 95° C. for about 10 seconds prior to being uniaxially oriented in the transverse direction to a draw ratio of 3.5:1. The oriented multilayer film was further heated at 225° C. for 10 seconds to increase crystallinity of the PET1 layers. The IR-reflective multilayer optical film (Film 2) was measured with a spectrophotometer (LAMBDA 950 UV/VIS/NIR SPECTROPHOTOMETER from Perkin-Elmer, Inc. of Waltham, Mass.) to have an average reflectivity of 96.1 percent over a bandwidth of 750-1350 nm.

Film 1 and Film 2 were laminated together using an optically clear adhesive obtained from 3M Company, St. Paul, Minn., as OPTICALLY CLEAR LAMINATING ADHESIVE PSA 8171 and then laminated again to a 0.25″ thick sheet of PMMA obtained from Arkema, Inc. under the trade designation PLEXIGLAS VO44. The resulting mirror laminate plates were then attached to the sides of an 80 watt crystalline silicon photovoltaic module (available under the trade designation SHARP 80W) with added hinges which allowed tracking of the sun as shown in FIGS. 8a-c.

Photovoltaic module power output was measured with a handheld voltage/current meter and calculated by multiplying open circuit voltage with closed loop current, and then multiplication again by a fill factor of 0.75, with the assumption that the fill factor was not changed by the concentrating mirrors. Temperature measurements were made both by taping multiple thermocouples to the backside of the PV module, and with the use of an infra-red pyrometer. Power output increases over a non-concentrated solar control photovoltaic module were measured as high as 400% in the mornings when the sun was low in the sky and 40% during mid-day. Measurements were made for several days in April of 2009 in Scandia, Minn., USA which is in a northern latitude and has a temperate climate. Considerable variability was observed when any clouds or haze occurred in the sky so averaging of the data was done. Power measurement results are shown in Table 2, below. The temperatures of the photovoltaic modules did not exceed 85° C.

TABLE 2

| | Control | Example 11 | |
|---|---|---|---|
| Time of Day | *Power(watts) | *Power(watts) | % increase |
| 8 AM | 15.4 | 76.3 | 396.1 |
| 9 AM | 36.9 | 104.9 | 184.4 |
| 10 AM | 57.8 | 114.8 | 98.7 |
| 11 AM | 77.2 | 120.8 | 56.6 |
| 12 PM | 80.4 | 113.2 | 40.8 |
| 1 PM | 80.9 | 110.0 | 35.9 |
| 2 PM | 74.2 | 108.4 | 46.1 |
| 3 PM | 68.2 | 106.6 | 56.3 |
| 4 PM | 58.0 | 108.1 | 86.4 |
| 5 PM | 32.3 | 105.0 | 225.6 |
| 6 PM | 16.9 | 79.8 | 372.9 |
| Sum = | 549 | 962.9 | 75.4 |

*assumes fill factor of .75

A compliant UV protective layer could be coextrusion coated onto the laminate of Film 1 and Film 2 using the method of Example 1. The trend in the power output observed in Table 2 would not be expected to change with the addition of the compliant UV protective layer.

Various modifications and alterations of this disclosure may be made by those skilled in the art without departing from the scope and spirit of this disclosure, and it should be understood that this disclosure is not to be unduly limited to the illustrative embodiments set forth herein.

What is claimed is:

1. A solar collection device comprising:
(a) one or more solar cells having an absorption bandwidth; and
(b) at least one solar concentrating mirror positioned in proximity to the one or more solar cells, wherein the at least one solar concentrating mirror comprises (i) a multilayer optical film having an optical stack having a plurality of alternating layers, the alternating layers having at least one birefringent polymer and at least one second polymer; and (ii) a UV protective layer applied onto a surface of the multilayer optical film, wherein the solar concentrating mirror reflects at least a major portion of the average light across the range of wavelengths that corresponds with the absorption bandwidth of the solar cell onto the solar cell and does not reflect onto the solar cell a major portion of light outside the absorption bandwidth of the solar cell; and
(c) a celestial tracking mechanism connected to at least one of the one or more solar cells or the at least one solar concentrating mirror.

2. The solar collection device according to claim 1, wherein the solar cell is selected from (i) a crystalline silicon single junction cell and the solar concentrating mirror reflects light from about 400 to about 1150 nm with at least a major portion of light greater than 1150 nm not reflected, (ii) a multi-junction GaAs cell and the solar concentrating mirror reflects light from about 350 nm to about 1750 nm with at least a major portion of light greater than 1750 nm not reflected, (iii) amorphous silicon single junction cell and the solar concentrating mirror reflects light from about 300 to about 720 nm with at least a major portion of light greater than 720 nm not reflected, (iv) a ribbon silicon cell and the solar concentrating mirror reflects light from about 400 to about 1150 nm with at least a major portion of light greater than 1150 nm not reflected, (v) a copper indium gallium selenide cell and the solar concentrating mirror reflects light from about 350 to about 1100 nm with at least a major portion of light greater than 1100 nm not reflected, or (vi) cadmium telluride cell and the solar concentrating mirror reflects light from about 400 to about 895 nm with at least a major portion of light greater than 895 nm not reflected.

3. The solar collection device according to claim 1, further comprising a thermal transfer device.

4. The solar collection device according to claim 1, wherein the light across the range of wavelengths that corresponds with the absorption bandwidth of the solar cell is concentrated onto the solar cell by an amount selected from greater than one, greater than 50, or greater than 100.

5. The solar collection device according to claim 1, wherein the solar concentrating mirror further comprises an infrared absorbing layer on the multilayer optical film opposite the UV protective layer to prevent back side infrared reflection; a reinforcing material selected from the group consisting of injection cladding, corrugation, ribs, foam spacer layers, or honeycomb structures on the multilayer optical film opposite the UV protective layer; or a combination thereof.

6. The solar collection device according to claim 1, wherein the solar concentrating mirror is formed in a parabolic or curved shape and the solar cell is positioned above the solar concentrating mirror.

7. The solar collection device according to claim 1, further comprising an antireflective surface structured film or coating positioned above a surface of the one or more solar cells.

8. The solar collection device according to claim 1, wherein the solar concentrating mirror is thermoformed and encompasses the solar cell such that light reflects onto more than one side of the solar cell.

9. The solar collection device according to claim 1, the solar concentrating mirror exhibits a reflectivity of 98% or greater of light corresponding to the absorption bandwidth of the selected solar cell.

10. The solar collection device according to claim 1, wherein the celestial tracking mechanism comprises one or more louvers pivotally mounted adjacent the one or more solar cells, wherein the one or more louvers comprises the at least one solar concentrating mirror.

11. The solar collection device according to claim 10, wherein the one or more louvers are connected to the one or more solar cells with hinges.

12. The solar collection device according to claim 10, wherein two louvers are pivotally mounted adjacent opposite sides of each solar cell.

13. The solar collection device according to claim 10, wherein the one or more solar cells are stationary.

14. The solar collection device according to claim 10, wherein each louver further comprises a substrate attached to a surface of the at least one solar concentrating mirror, wherein the substrate comprises at least one of a glass sheet, a polymeric sheet, a structured polymer sheet comprising a corrugated laminate or a multi-wall polymer sheet construction, a polymer fiber composite, or a black painted metal.

15. The solar collection device according to claim 10, wherein the light across the range of wavelengths that corresponds with the absorption bandwidth of the solar cell is concentrated onto the solar cell by an amount in a range from 1.1 to about 5.

16. The solar collection device according to claim 1, wherein at least one of the one or more solar cells or the at least one solar concentrating mirror is pivotally mounted on a frame.

17. The solar collection device according to claim 16, wherein the at least one solar concentrating mirror is formed into a trough with the one or more solar cells placed inside the trough such that both the at least one solar concentrating mirror and the one or more solar cells are pivotally mounted on a frame.

18. A solar collection device according to claim 1, further comprising at least one infrared mirror, at least one UV mirror, or combinations thereof.

19. A method of collecting solar energy comprising positioning a louver comprising a solar concentrating mirror in proximity to a solar cell wherein the solar concentrating mirror comprises (i) a multilayer optical film having an optical stack having a plurality of alternating layers, the alternating layers having at least one birefringent polymer and at least one second polymer; and (ii) a UV protective layer applied onto a surface of the multilayer optical film, wherein the solar concentrating mirror reflects at least a major portion of the average light across the range of wavelengths that corresponds with the absorption bandwidth of the solar cell onto the solar cell and does not reflect onto the solar cell a major portion of light outside the absorption bandwidth of the solar cell, and wherein the louver comprises a celestial tracking mechanism.

20. The method according to claim 19, wherein the light across the range of wavelengths that corresponds with the absorption bandwidth of the solar cell is concentrated onto the solar cell by an amount selected from greater than one, greater than 50, or greater than 100.
